(19) United States
(12) Patent Application Publication
(10) Pub. No.: US 2018/0037757 A1
(43) Pub. Date: Feb. 8, 2018

(54) A PARTICLE DISPERSION

(71) Applicant: PERPETUUS RESEARCH & DEVELOPMENT LIMITED, London (GB)

(72) Inventors: Ian Walters, Ammanford (GB); Rebecca Phillips, Newport (GB)

(73) Assignee: PERPETUUS RESEARCH & DEVELOPMENT LIMITED, London (GB)

(21) Appl. No.: 15/553,895

(22) PCT Filed: Feb. 24, 2016
(86) PCT No.: PCT/GB2016/050469

§ 371 Date: Aug. 25, 2017

(30) Foreign Application Priority Data
Feb. 27, 2015 (GB) 1503398.8

(51) Int. Cl. C09D 11/037; C09D 11/102; H05K 1/09; C09D 11/52; C09D 17/00; C01B 32/182; C09D 11/033; C09D 11/38

(52) U.S. Cl. CPC C09D 11/037; C09D 11/033; C09D 11/102; C09D 11/38; C09D 11/52; C09D 17/002; C09D 17/005; C09D 17/006; C01B 32/182; H05K 1/097

(57) ABSTRACT

A particle dispersion (1) is disclosed that comprises a binder component (2) and a solvent component (3). The binder component (2) is dissolvable within the solvent component (3). The particle dispersion (1) also comprises a carbon based nano particle (4), wherein the carbon based nano particle (4) is uniformly dispersed within the binder (2).

This invention relates to a particle dispersion and a method for preparing a particle dispersion, in particular an ink for printing onto a substrate.

Inks can be used for many applications including flexible conductive circuitry, LED's, sensors, solar cells, and can also be used for encoding information and tagging articles. In the case of the inks to be applied to conductable circuits, in general, the inks incorporate a metal powder or graphite as the conductive medium. However, there are various pros and cons with using the existing conductive materials. For example, whilst inks containing silver are chemically stable and possess excellent electrical properties, this comes at a high cost. Copper inks are relatively cheaper than the silver equivalent, but are easily oxidised and are conductively unstable. Whereas, graphite inks are low in cost, easy to oxidise but possess low conductivities and mechanical properties, since the ink is easily scratched and shed from the substrate surface to which it is applied and cured.

A preferred alternative contender for the conductive material is graphene which has improved electrical and mechanical properties that can be applied in many applications that are produced by the method of printing to produce a film or coating. For example graphene possesses excellent light transmittance and chemical stability, excellent conductivity properties and is an extremely strong and resilient material.

It is known to use graphene oxide in inks for inkjet printing, but due to the necessity to reduce graphene oxide it is difficult to fully restore the electronic properties of graphene, and as such the performance of the ink is not usually satisfactory. In the art it is usually expected for graphene oxide to contain an average of 29% oxygen.

Alternatively, graphite and graphite derivatives are used as the raw material in inks. The graphite is then manipulated to provide graphene which provides desirable properties to the ink. The difficulty however, is in dispersing the graphene within the binding agent. Therefore, further additives and techniques are required to form the graphene dispersion, which can contaminate the ink and alter the conductive and mechanical properties of the ink. This addition of further additives can be a time consuming, expensive and complicated process. For example, in CN103468057 a dispersing agent may need to be applied to disperse graphene through an adhesive resin, however, this technique also requires the need for a defoaming agent and a stabilizing agent to be applied. Residues of the additives can adversely alter the properties of the ink.

Alternatively, in CN103839608 ultrasound is applied to a graphite starter material to form separate graphene particles in the dispersion. The graphene particles are then dispersed in an organic solvent and then injected into the ink cartridge. There is no mention in CN103839608 of how the graphene is dispersed, but it is known to be difficult to uniformly disperse the graphene through the binder component.

Therefore, the present invention and its embodiments are intended to address at least some of the above described problems and desires. In particular the ink provided has improved mechanical and electrical properties that can be adapted dependent upon the application of interest. In particular the cured ink provides a flexible structure that has good adhesive properties with the surface of the substrate to which it is applied. Further, a uniform dispersion of the particulate through the binder is provided.

According to a first aspect of the invention there is provided a particle dispersion comprising

a binder component,

a solvent component, the binder component being dissolvable within the solvent component and

a carbon based nano particle, wherein the carbon based nano particle is uniformly dispersed within the binder.

Both the binder and the carbon based nanoparticle may be functionalised with complimentary functional groups so that the binder preferentially binds to the carbon based nano particle.

The bonding may be hydrogen, or another form of dipole bonding, covalent bonding or ionic bonding.

The carbon based nano particle may be functionalised with a functional group selected from the group comprising oxygen, carboxylic acid or a primary, secondary or tertiary amine.

The carbon based nano particle may be functionalised with a metal.

The binder may be functionalised with a functional group selected from the group comprising hydroxyl, methylol, carboxylic groups, epoxy, isocyanate, amide or imide.

The binder may be a polymer.

The polymer may be a conductive polymer.

The conductive polymer may be selected from the group comprising polythiophene and polycationic polymer.

The polymer may be selected from the group comprising poly(3,4-ethylenedioxythiophene (PEDOT), poly(3,4-ethylenedioxythiophene)-polystyrene sulfonic acid (PEDOT:PSS), polyaniline and polypyrrole.

The polymer may be a thermosetting plastic.

The thermosetting plastic may be selected from the group comprising Phenolic Resoles and amino resins, blocked Isocyanate resins, epoxy resins and unsaturated polyester resins.

The polymer may be a thermoplastic.

The thermoplastic may be selected from the group comprising polyamides, polyurethanes, Acrylic copolymers, Polyesters, bis-Phenol Epoxy resins and Cellulosic materials.

The carbon based nano particle may comprise graphene nanoplatelets.

The carbon based nano particle may comprise a graphitic material comprising a first and second graphitic layer, the first graphitic layer spaced apart from the second graphitic layer, wherein the graphitic layer is interdispersible within the binder.

The first and second graphitic layers may comprise nano-platelets.

The first and second graphitic layers may comprise an undulating structure.

The first and second graphitic layers may be in a stacked arrangement.

The first layer may be a first substructure and the second layer may be a second substructure including a stack of graphitic layers in which separation between successive stacked substructures may be greater than the separation between successive graphitic layers in each substructure.

The carbon based nanostructure comprises carbon nanotubes.

The solvent may comprise one or more of an Aromatic or an Aliphatic Hydrocarbon, Halogenated Hydrocarbons, Alcohols, Ketones Esters and Aldehydes, Polyhydric Alcohols, Glycol ethers and their Esters, low molecular weight Polyamines, Urethane prepolymers, epoxy prepolymers, Vinyl Esters and Acrylates.

The carbon based nano particle component may be present in a range from about 1 wt % to about 5 wt %.

The binder component may be present in a range from about 10 wt % to about 50 wt %.

The binding material, solvent and carbon based nano particle may form an ink.

In a further embodiment of the invention there is provided a method of preparing a film comprising evaporating the solvent and shrinking the distance between binder components so as to shrink the volume of the mixture.

The method may further comprise applying a particle dispersion as here-before described onto a substrate;

evaporating the applied particle dispersion; and subsequently

curing the binder so as to form a matrix containing the carbon based nano particles.

The curing may take place at a temperature of between 60° C. to 130° C.

The binder may be a thermosetting material and the method further comprises cross-linking the thermosetting material so as to form a cross linked network.

In a further method according to the invention there is provided a method of preparing a particulate dispersion comprising:

dissolving a functionalised binder in a solvent to form a first mixture;

adding a functionalised carbon based nano-particle to the first mixture to form a second mixture;

mixing the second mixture until a predetermined property of the mixture is achieved.

The predetermined property may relate to the particle size of the carbon based particulate material.

The rheology of the second mixture may be adjusted according to a printing application of the particulate dispersion.

The method may further comprise applying the particle dispersion to a substrate by slot die coating, flexographic printing, screen printing, ink jet printing, stencil printing or 3D printing.

Whilst the invention has been described above it extends to any inventive combination of the features set out above, or in the following description, drawings or claims. For example, any features described in relation to any one aspect of the invention is understood to be disclosed also in relation to any other aspect of the invention.

The invention will now be described, by way of example only, with reference to the accompanying drawings, in which:—

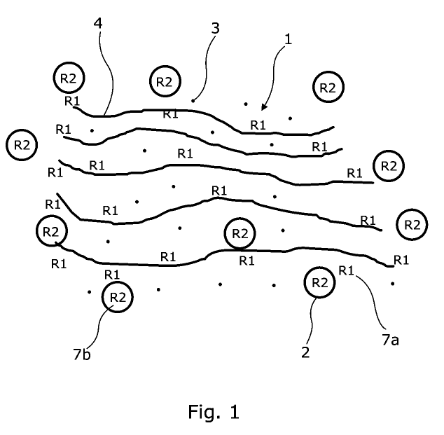

FIG. 1 is a schematic view of a particle dispersion according to the invention;

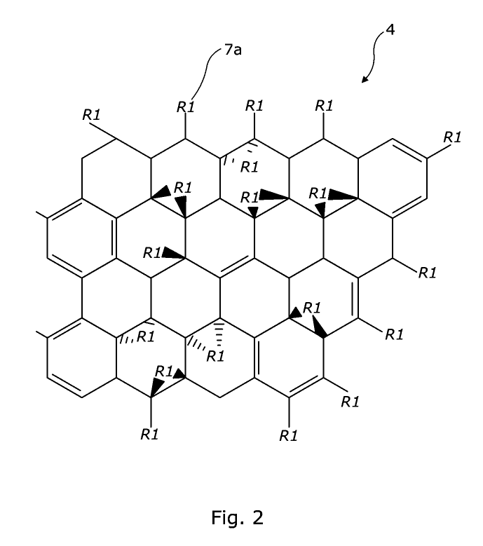

FIG. 2 is a chemical structure of a functionalised graphene according to the invention;

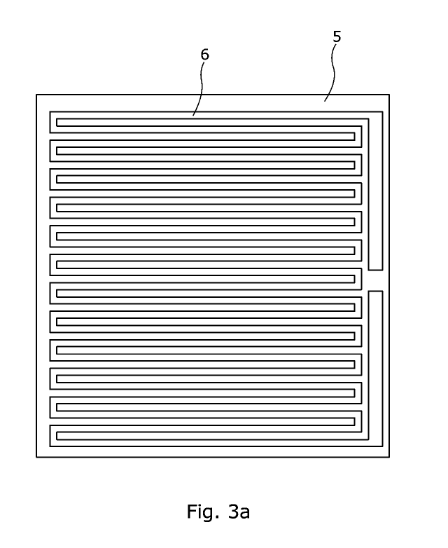

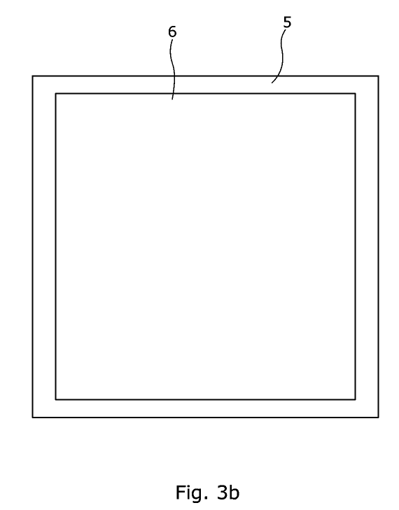

FIG. 3a is a view of a patterned film formed on a substrate;

FIG. 3b is a view of a film formed on a substrate;

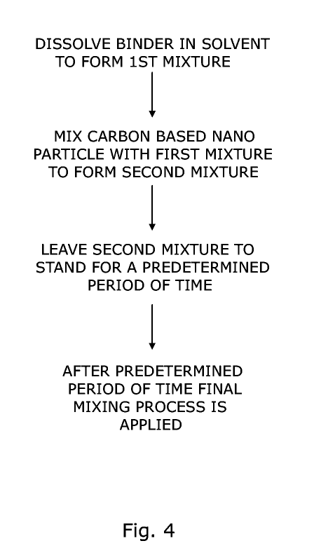

FIG. 4 is a flow diagram of the method of preparing the particle dispersion; and

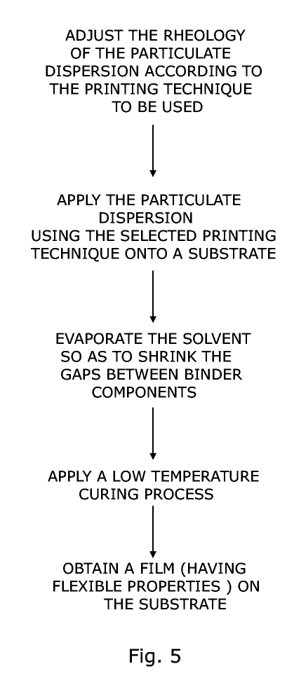

FIG. 5 is a flow diagram of a method of producing a flexible film.

Referring firstly to FIG. 1, there is shown a particle dispersion 1 comprising a binder component 2, a solvent component 3 and a carbon based nano particle 4, wherein the carbon based nano particle 4 is uniformly dispersed within the binder component 2. The carbon based nano particle 4 may, for example, comprise graphene nanoplatelets. Graphene provides many desirable properties that may be desirable for a particle dispersion, for example and ink. This is because graphene is electrically conductive and possesses a strong and durable structure.

The binder component 2 is dissolvable within the solvent component 3. The particle dispersion 1 comprises an ink that can be printed onto a substrate 5 so as to form a film or layer 6 thereon.

At least some of the carbon based nanoparticle may be surface modified by functionalisation 7a as shown in FIG. 2. The functionalised group 7a may be selected from the group containing Ag, Mn, Fe, Co, OH, CN, COOH, NH, S etc.

The complimentary functionalisation can be performed in order to ensure that the uniform distribution of the carbon based nanoparticle 4 is achieved within the binder 2. To enable this, the binder 2 is also functionalised 7b and the binder functionality 7b is selected to compliment the functional group 7a of the carbon based nanoparticle 4. This ensures that the carbon based nano particle 4 is attracted towards the binder 2 and that the binder 2 preferentially binds to the carbon based nano particle 4. For example if the carbon based nano particle 4 has COOH groups, then the binder polymer 2 selected will have a complimenting functionality such as OH. The bonding will be provided by hydrogen bonding in this instance, but different complimentary functional groups may be applied that will provide different types of bonding between the carbon based nano particle 4 and the binder component 2, for example co-valent or ionic bonding may be provided instead of dipole bonding.

The carbon based nano-particle 4 may, for example, include a functional group 7 selected from the group comprising oxygen, carboxylic acid or a primary, secondary or tertiary amine. Alternatively, a functionalisation using a metal may be provided. In the case that the carbon based nano-particle 4 is graphene which is functionalised with oxygen, an average percentage of oxygen applied is around 5%, rather than 29% which is usually expected from graphene oxide.

The carbon based nano particle component 4 is present in the particulate dispersion in a range from about 1 wt % to about 5 wt %.

The binder 2 is, for example, functionalised with a functional group 7b selected from the group comprising hydroxyl, alkylol, carboxyl, epoxy, isocyanate, amine or imide. Ideally, the functionality 7b is pendant to the main polymer backbone so as to restrict the effect of steric hindrance, although this need not be the case.

The binder component 2 has a lower limit of 10 wt % and an upper limit of 50 wt %.

The contribution of the carbon based nano particle 4 and the binder 2 may be in a range which extends from any of the lower bounds defined above to any of the upper bounds defined above. Further, any combination of the above-mentioned ranges may be provided to form the particulate dispersion.

The binder 2 is a polymer 2a that consists of at least one of a thermoplastic resin, a thermosetting resin, cellulose, a conductive polymer or any combination thereof. The conductive polymer includes at least one of polythiophene and polycationic polymer. More specifically; the polymer binder 2a is selected from at least one of poly(3,4-ethylenedioxythiophene (PEDOT), poly(3,4-ethylenedioxythiophene)-polystyrene sulfonic acid (PEDOT:PSS), polyaniline and polypyrrole. The polymers 2a are selected depending on the intended end use. For example the polymer 2a should be a film forming material where an ink or coating 1a is intended for end use. Alternatively, the polymer 2a should be soluble or in inexpensive organic solvents where non-aqueous systems are required. Further alternatively, the polymer 2a should be soluble or miscible with water where aqueous coating systems are required.

In each of the above cases, the polymer 2a should contain functional groups 7b that compliment the functionality 7a contained on the graphene 4a to maximise wetting and hence dispersion of the graphene 4a.

The thermosetting polymer binder 2b is a low molecular weight soluble polymer that is capable of further reaction, on application of heat or a catalyst, to form a high molecular weight highly branched or cross-linked insoluble polymer network. For example suitable types of thermosetting polymers 2b for use as binders for carbon based nanostructures 4 include Phenolic Resoles and Amino resins, blocked Isocyanate resins, epoxy resins, unsaturated polyester resins etc. In the case of thermosetting polymers, the polymer 2b should contain groups capable of reacting further to form cross-linked networks where physical properties such as heat resistance, toughness and strength and chemical resistance such as solvent resistance, water resistance, acid resistance and weathering are required for an end use with structural applications.

Alternatively, the polymer 2c is a thermoplastic. Thermoplastic polymers 2c suitable for use as binders for carbon based nanostructures include polyamides, polyurethanes, Acrylic copolymers, Polyesters, bis-Phenol Epoxy resins and Cellulosic materials.

The solvents 3, in addition to being inexpensive, non-hazardous to the environment, capable of removal at relatively low temperatures with conventional equipment such as ovens, belt dryers, UV and IR ovens must be capable of dissolving the polymeric binder selected. The solvent 3 is selected from a group comprising Aromatic and Aliphatic Hydrocarbons, Halogenated Hydrocarbons, Alcohols, Ketones Esters and Aldehydes, Polyhydric Alcohols, Glycol ethers and their Esters, low molecular weight Polyamines, Urethane prepolymers, epoxy prepolymers, Vinyl Esters and Acrylates. It is important that the solvent 3 is capable of dissolving the binder therein so that it may suitably wet the surface of the carbon based nano particle 4 that is also applied thereto.

As shown in FIG. 4, in use, to form the particle dispersion 1, for example an ink 1a, the polymer binder 2a and the solvent 3 are mixed together to form a mixture 8. The carbon based nanoparticles 4 are added on a powder form to the mixture 8 and are incorporated into the stirring until the resulting mixture forms a homogeneous paste. Therefore, this mixing process ensures that the binder 2, which is dissolved in the solvent 3, flows over the surfaces of the carbon based nanoparticles 4 so as to surround the nanoparticles 4 in such a way that any air contaminants are displaced. This process is known as ‘wetting’.

The mixture 8 is then left to stand at room temperature for a minimum of 8 hours to ensure that the powder has fully adsorbed the polymer binder 2a and the solvent 3.

The mixing process is then continued using a 3-roll pressure mill until the required particle size and dispersion is achieved. A typical particle size for a screen printable ink 1a would be less than 5 microns. As shown in FIG. 5, the rheology of the resulting paste, which is relative to the type and degree of functionalisation, is adjusted as necessary using known techniques so as to suit the type of coating technique to be employed. For example slot die coating, flexographic printing, screen printing, ink jet printing, stencil printing, 3D printing etc. Once the particulate dispersion 1 is applied onto a substrate 5 using the desired printing technique, an evaporation step is applied that removes the solvent 3 and causes the distance between binder 2 components to shrink, thereby reducing the volume of the printed ink 1a. As a consequence of this shrinkage a matrix structure is formed containing the carbon based nanoparticles 4.

Without limiting to a particular theory or conjecture it is believed that the film 6 is formed chemically and the physical and chemical properties of the film are enhanced, for example the film 6 is advantageously flexible, possesses more stable adhesive properties and desirable electrical properties. The flexibility is also aided by the small particle size of the carbon based nanoparticle 4, for example graphene.

The curing step takes place at a temperature of between 60° C. to 130° C. The temperature of the curing can vary based on the desired time for the cure. This low curing temperature is beneficial since minimal energy is required to provide the necessary curing temperature providing a cost effective manufacturing process.

The low film forming temperature in conjunction with the fact that the ink 1a has been found to show a good bonding capability with the substrate due to its enhanced adhesive property makes it ideal to use on plastic substrates with relatively low deformation temperatures such as PET, Polyester, PVC, Nitrocellulose, Polycarbonate etc. This allows for the film 6 to be used for state of the art foldable or bendable circuitry. Ultimately, the substrate 5 should be selected carefully such that the temperature of the cure does not exceed the melting point of the substrate material.

Such a film 6 is beneficial in the medical applications, and in fact in any application requiring a flexible and durable circuitry.

In the case that the binder 2 comprises a thermosetting material 2c the combination of the functional groups 7a, 7b provide the attraction required to bring the binder 2 and the carbon based nano-particle 4 together. Then the evaporation and the subsequent curing stages allows for cross-linking reactions to occur during film formation such that a cross linked network is formed.

Providing defects on the surface of the carbon based nano particle 4 can aid the functionalisation process.

A resulting film 6 according to the invention as shown in FIG. 3a and FIG. 3b, displays enhanced conductivity whereby a resistivity range of between 150 ohms per square to sub 1 ohm per square at a film 6 thickness of 25 microns can be achieved, whereby the resistivity value depends on the intended end use of the film 6. For example a sub 5 ohms per square film has been measured. In comparison it is normal for carbon based inks to provide 100 ohms per square. Therefore, a film 6 having a conductivity of below 5 ohms per square provides a vast improvement on the range of applications of the film 6.

The below table demonstrates physical properties of the ink 1a and the film 6 that have been demonstrated:

| | |
|---|---|
| Solids Content at 130° C., 130 minutes | 39.0-42.0% |
| Viscosity Haake VT550, PK1.1° at 230 sec−1 | 10.0-15.0 Pas |
| at 25° C. | |
| Sheet Resistivity | <5 ohms/sq normalised |
| Printed through 230 stainless steel | to 25 μm |
| mesh with 13 micron emulsion | |
| Cured Thickness | Typically 8-12 microns |
| Printed through a 230 stainless steel | |
| mesh with 13 micron emulsion | |

Various modifications to the principles described above would suggest themselves to the skilled person. For example, in an alternative embodiment the carbon based nano particle 4 is a graphitic material as described in co-pending application no. GB 1405616.2 comprising a first and second graphitic layer, the first graphitic layer spaced apart from the second graphitic layer (not shown), wherein the graphitic layer is interdispersible within the binder. The first and second graphitic layers comprise nano-platelets comprising an undulating structure. The first and second graphitic layers are in a stacked arrangement. The first layer is a first substructure and the second layer is a second substructure including a stack of graphitic layers in which separation between successive stacked substructures is greater than the separation between successive graphitic layers in each substructure. This arrangement is beneficial since the ability of stacked layers to slide with respect to each other provides an extra mechanism for dispersing the graphite and provides yet a further improvement to the uniform distribution of the graphene through the binder. Reference is made to GB 1405616.2 and any other application claiming priority from GB 1405616.2.

Alternatively, carbon nano tubes may be applied with the binder. Therefore, the carbon nano tubes are the carbon based nano particle 4.

Generally, nano particles are considered to be particles having a characteristic dimension of less than 1000 nm. Particles of the invention may have a characteristic dimension of less than 1000 nm, but in some embodiments particles of the invention have characteristic dimensions (e.g., thickness and width) which are all 1000 nm or greater. The term “characteristic dimension”, as is generally understood and as is used herein, relates to an overall dimension of the particle considered as a whole entity. However, in general the separation between successive sub-structures and the stack thicknesses of the sub-structures are less than 1000 nm.

The separation between successive stacked sub-structures may be at least 2 nm, preferably at least 5 nm, more preferably at least 10 nm. The separation between successive stacked sub-structures may be less than or equal to 100 nm, preferably less than or equal to 50 nm, more preferably less than or equal to 30 nm, most preferably less than or equal to 20 nm. The separation between successive stacked sub-structures may be in a range which extends from any of the lower bounds defined above to any of the upper bounds defined above. In particular, the separation between successive stacked sub-structures may be in the range 2 to 100 nm, preferably 5 to 50 nm, more preferably 10 to 30 nm, most preferably 10 to 20 nm.

The sub-structures may each have a stack thickness which is at least 0.7 nm, preferably at least 1 nm. The sub-structures may each have a stack thickness which is 15 nm or less, preferably 4 nm or less. The sub-structures may each have a stack thickness which is in the range 0.7 to 15 nm, preferably 0.7 to 4 nm. The sub-structures may each have a stack thickness which is in the range 1 to 15 nm or in the range 1 to 4 nm.

Each sub-structure may include a stack of between 2 and 12 graphene layers. It is possible for the particle to include single layers of graphene as well.

The sub-structures may be regarded as having some similarity to graphene nanoplatelets, since the basic sub-structure unit is a stacking of graphene layers. However, the number of layers of graphene, their separation, the stack height and the width of the sub-structures may be similar or dissimilar to GNPs. Additionally, the topography of sub-structures may be similar or dissimilar to GNPs. In a number of embodiments, the sub-structures and the particles themselves exhibit a wavy or undulating topography.

The sub-structures each have a stack thickness. The stack thicknesses may be less than the separation between successive stack sub-structures.

The particle may have a thickness in the range 0.7 to 5 microns, preferably 1 to 5 microns, more preferably 1.5 to 3 microns. For the avoidance of doubt, the term “thickness” relates to a dimension along which the sub-structures are stacked.

The particle may have a width in the range 1 to 15 microns, preferably 1 to 8 microns, more preferably 2 to 5 microns. For the avoidance of doubt, the term “width” relates to a dimension which is perpendicular or significantly perpendicular to the dimension corresponding to the thickness of the particle.

The sub-structures may have a nett negative charge. Without wishing to be bound by any particular theory or conjecture, it is believed that the presence of the nett negative charges may at least assist in producing and/or retaining the relatively large separations between successive stack sub-structures in relation to the separation between successive graphene layers in each sub-structure. Again without wishing to be bound by any particular theory or conjecture, it is believed that the presence of the nett negative charges may at least assist in enhancing friability.

In a yet further embodiment of the invention CNT's are used in combination with the graphene stacks. The sliding effect of the stacks offers a more even dispersion of the CNT's compared to other techniques known in the art. A plasma reactor (not shown) as described in co-pending application no. GB1420103.2 can be used to deposit the functional group onto the ends of the CNTs. Reference is made to GB 1420103.2 and any other application claiming priority from GB 1420103.2.

The commercial product is provided in a 2 component pack so as to prevent any reaction occurring at room temperature during storage or transport.

The 2 component pack comprises the functionalised binder 2 terminated by a blocking group in the standard way.

Whilst it has been described for the ink 1a to form a film 6 having electrically conductive properties, it has also been shown for the ink 1a to form a film 6 having electrically insulating properties.

The temperature of the cure may be as low as room temperature, however the time for the cure will take several days and due to this timescale a cure temperature of less than 60° C. is not deemed to be commercially useful. Also when using a two-pack system it is preferable for this to be as stable as possible at room temperature for transportation and storage purposes. This allows more control of the preparation of the ink 1a once the binder 3 is removed, since heat is also required to initiate the curing procedure.

1. A particle dispersion comprising
a binder component,
a solvent component,
the binder component being dissolvable within the solvent component and
a carbon based nano particle, wherein the carbon based nano particle is uniformly dispersed within the binder.

2. A particulate dispersion according to claim 1, wherein both the binder and the carbon based nanoparticle are functionalised with complimentary functional groups so that the binder preferentially binds to the carbon based nano particle.

3. A particulate dispersion according to claim 1 wherein the carbon based nano particle is functionalised with a functional group selected from the group comprising oxygen, carboxylic acid or a primary, secondary or tertiary amine.

4. A particulate dispersion according to claim 1, wherein the carbon based nano particle is functionalised with a metal.

5. A particulate dispersion according to claim 1 wherein the binder is functionalised with a functional group selected from the group comprising hydroxyl, methylol, carboxylic groups, epoxy, isocyanate, amide or imide.

6. A particulate dispersion according to claim 1, wherein the binder is a polymer.

7.-13. (canceled)

14. A particulate dispersion according to claim 1, wherein the carbon based nano particle comprises graphene nanoplatelets.

15. A particulate dispersion according to claim 1, wherein the carbon based nano particle comprises a graphitic material comprising a first and second graphitic layer, the first graphitic layer spaced apart from the second graphitic layer, wherein the graphitic layer is interdispersible within the binder.

16. A particulate dispersion according to claim 15, wherein the first and second graphitic layers comprise nano-platelets.

17. A particulate dispersion according to claim 15, wherein the first and second graphitic layers comprise an undulating structure.

18. A particulate dispersion according to claim 15, wherein the first and second graphitic layers are in a stacked arrangement.

19. A particulate dispersion according to claim 15, wherein the first layer is a first substructure and the second layer is a second substructure including a stack of graphitic layers in which separation between successive stacked substructures is greater than the separation between successive graphitic layers in each substructure.

20. A particulate dispersion according to claim 1, wherein the carbon based nanostructure comprises carbon nanotubes.

21. (canceled)

22. A particulate dispersion according to claim 1, wherein the carbon based nano particle component is present in a range from about 1 wt % to about 5 wt %.

23. A particulate dispersion according to claim 1, wherein the binder component is present in a range from about 10 wt % to about 50 wt %.

24. A particulate dispersion according to claim 1, wherein the binding material, solvent and carbon based nano particle form an ink.

25. (canceled)

26. A method of forming a film, the method comprising applying a particle dispersion according to claim 1 onto a substrate; evaporating the applied particle dispersion; and subsequently curing the binder so as to form a matrix containing the carbon based nano particles.

27.-28. (canceled)

29. A method of preparing a particulate dispersion comprising dissolving a functionalised binder in a solvent to form a first mixture; adding a functionalised carbon based nano-particle to the first mixture to form a second mixture; mixing the second mixture until a predetermined property of the mixture is achieved.

30. A method according to claim 29, wherein the predetermined property relates to the particle size of the functionalised carbon based nano-particle.

31. A method according to claim 29, wherein the rheology of the second mixture is adjusted according to a printing application of the particulate dispersion.

32.-35. (canceled)
